(19) United States
(12) Patent Application Publication
(10) Pub. No.: US 2002/0025677 A1
(43) Pub. Date: Feb. 28, 2002

(54) Dry etching method and apparatus

(76) Inventor: Shinzo Uchiyama, Tochigi (JP)

Correspondence Address: FITZPATRICK CELLA HARPER & SCINTO, 30 ROCKEFELLER PLAZA, NEW YORK, NY, 10112, US

(21) Appl. No.: 09/909,819

(22) Filed: Jul. 23, 2001

(30) Foreign Application Priority Data
Jul. 27, 2000 (JP) 226362/2000

(51) Int. Cl. C23F 1/02; H01L 21/302; H01L 21/461

(52) U.S. Cl. 438/689; 156/345

(57) ABSTRACT

To dry-etch a thin metal film in a trench such as an line trench in a semiconductor device with good reproducibility independently of the longitudinal length of the trench and without requiring etching end detection, a metal film is deposited and buried in a through hole or line trench of the semiconductor device and then anisotropically dry-etched by irradiating the object to be processed with charged particles. At this time, the object to be processed is kept at a predetermined electric potential, and a magnetic field is almost vertically applied to the object to be processed such that charged particles are incident on the object to be processed at an incident angle θ while spirally moving, thereby anisotropically dry-etching the metal film outside the trench.

### BACKGROUND OF THE INVENTION

1. Field of the Invention

The present invention relates to a dry etching method and apparatus used to manufacture a semiconductor device.

2. Related Background Art

In a dry etching method for a thin film such as an interconnection metal film in a semiconductor device, normally, anisotropic etching is vertically executed for an object to be processed using a photoresist as a mask, and an interconnection layer is vertically processed to perform micropatterning.

In addition, as a method of forming a through hole between the upper and lower interconnection layers of a semiconductor device and forming a metal layer only in the through hole to electrically connect the upper and lower interconnection layers, a dry etching method disclosed in Japanese Laid-Open Patent Application No. 5-121376 is known. In this conventional dry etching method, as shown in FIG. 5A, a first interconnection layer 102 is formed on a first interlayer 101, and then, a second interlayer 103 is formed. A through hole 104a as a concave portion is formed using a photoresist as a mask. After the photoresist is removed, a metal film is deposited in the through hole to form a metal plug 104 in the through hole. After that, the semiconductor device that is rotating on its axis is irradiated with etchant gas particles 105 at an incident angle θ, thereby obliquely anisotropically dry-etching the metal film, as shown in FIG. 5B.

According to this method, the metal plug 104 in the through hole 104a is etched to a position slightly retreated from the surface of the insulating interlayer 103 and is not etched anymore. This is because the etchant gas particles 105 cannot enter the metal plug beyond the depth corresponding to the shadow of the through hole. Letting θ be the incident angle of the etchant gas particles with respect to the semiconductor device and w be the diameter of the through hole, a retreat amount x of the etched metal plug is given by

x=w·tanθ

For example, when w=1 μm and θ=1°, etching stops at a position retreated from the surface by x=17 nm.

As a characteristic feature of the above-described dry etching method, the shape of the metal plug buried in the through hole can be formed with good reproducibility without requiring dry etching end detection.

However, when the above-described conventional dry etching method is applied to a so-called dual damascene process for simultaneously forming a line trench and through hole, as shown in FIGS. 6A and 6B, the metal film in the line trench as a concave portion is excessively etched, and a metal film having a sufficient thickness cannot be left in the line trench. That is, when a metal film 106 is deposited and buried in a concave portion formed from a through hole 106a and line trench 106b, and then, the semiconductor device which is rotating on its axis is irradiated with the etchant gas particles 105 at the incident angle θ to obliquely anisotropically etch the metal film 106, as shown in FIG. 6A, most of the metal film 106 buried in the line trench 106b is etched, as shown in FIG. 6B, and the metal film 106 having a sufficient thickness cannot be left in the line trench 106b. This is because the line trench 106b is long in the longitudinal direction, the shadow of the line trench 106b is formed at a position deeper than the trench depth, and the etchant gas particles 105 reach the bottom of the line trench 106b.

For example, when an object to be processed, whose metal line trench has a longitudinal length w=10 mm, is etched by an etchant gas particles at an incident angle θ=1°, etching stops at a position retreated from the surface by (x=) 170 μm. That is, the retreat amount of the metal film becomes larger than the depth of the line trench, and the metal film in the line trench is entirely etched.

As described above, the conventional dry etching method is advantageous in forming the shape of the metal plug with good reproducibility without requiring dry etching end detection, though the method cannot be effectively employed for etching of a metal film deposited and buried in a trench that is long in the longitudinal direction, like the line trench of a semiconductor device.

### SUMMARY OF THE INVENTION

It is an object of the present invention to provide a dry etching method and apparatus and a structure manufacturing method, which can obtain a desired shape with good reproducibility.

It is another object of the present invention to provide a dry etching method and apparatus and a structure manufacturing method, which can execute dry etching capable of forming a metal thin film in a trench with good reproducibility independently of the longitudinal length of the trench such as an line trench in a semiconductor device.

It is still another object of the present invention to provide a dry etching method and apparatus and a structure manufacturing method, which require no etching end detection.

According to the present invention, there is provided a dry etching method of irradiating an object to be processed, which has a thin film deposited on a surface thereof having a trench or hole, with charged particles to remove the thin film outside the trench or hole, comprising the steps of making the charged particles spirally move by a magnetic field substantially vertically applied to the object to be processed, maintaining the object to be processed at a positive electric potential, and making the charged particles incident on the object to be processed, thereby anisotropically dry etching the thin film.

The dry etching method of the present invention preferably further comprises the step of keeping the object to be processed at a predetermined electric potential.

According to the present invention, there is also provided a dry etching method of irradiating an object to be processed, which has a thin film deposited on a surface having a trench or hole, with charged particles to remove the thin film outside the trench or hole, comprising the steps of keeping the object to be processed at a predetermined electric potential, making the charged particles incident on the object to be processed while making the charged particles spirally move by a magnetic field substantially vertically applied to the object to be processed, thereby anisotropically dry etching the thin film.

In the dry etching method of the present invention, the charged particles are preferably incident at an angle of 0° to 45°, and more preferably, at an angle of 0° to 10° with respect to a horizontal direction of the object to be processed. The magnetic field is preferably applied while making a line of magnetic force cross the surface of the object to be processed vertically or at an angle less than 10°. An intensity of the magnetic field is preferably 0.1 tesla or more, and more preferably, 1.0 tesla or more.

In the dry etching method of the present invention, the thin film deposited on the object to be processed can be formed from a material selected from the group consisting of a polysilicon film, a nitride film and silicide film of a refractory metal as an interconnection metal film, and alloy films containing copper, aluminum, titanium, and tantalum.

According to the present invention, there is also provided a dry etching apparatus having holding means for holding an object to be processed, a reactor capable of accommodating the processed object holding means in an accommodation space, and plasma generation means for supplying charged particles to the accommodation space, comprising charged particle spiral motion means, arranged around the accommodation space, for making the charged particles spirally move.

In the dry etching apparatus of the present invention, the charged particle spiral motion means is preferably arranged around the processed object holding means accommodated in the accommodation space, or at a position where the charged particles can be made to spirally move on the processed object holding means.

In the dry etching apparatus of the present invention, the charged particle spiral motion means preferably has an electromagnetic coil or permanent magnet.

In the dry etching apparatus of the present invention, the charged particle spiral motion means preferably generates a magnetic field having a line of magnetic force that crosses a surface of the object to be processed, which is held by the processed object holding means, vertically or at an angle less than 10°.

In the dry etching apparatus of the present invention, the reactor preferably has a charged particle supply path tilted with respect to a line perpendicular to a holding surface of the processed object holding means.

The dry etching apparatus of the present invention preferably further comprises control means for controlling an incident angle and/or a variation in incident angle of the charged particles on the processed object holding means.

According to the present invention, there is also provided a method of manufacturing a structure in which a concave portion formed in a first layer is filled with a material different from that of the first layer, comprising the steps of:

depositing a second layer made of the material on an upper surface of the first layer having the concave portion; and

executing dry etching to remove the second layer deposited outside the concave portion,

wherein the dry etching step comprises the step of maintaining an etched surface side at a predetermined electric potential and substantially vertically applying a magnetic field to the etched surface to make charged particles become incident on the etched surface while spirally moving.

In the structure manufacturing method of the present invention, the etched surface side is preferably controlled to have a positive electric potential.

In the structure manufacturing method of the present invention, a predetermined voltage is preferably applied to support means for supporting an object to be processed having the first layer.

In the structure manufacturing method of the present invention, the charged particles preferably become incident at an angle of 0° (exclusive) to 45° (inclusive) with respect to a direction parallel to the etched surface.

In the structure manufacturing method of the present invention, the magnetic field is preferably applied while making a line of magnetic force cross the etched surface vertically or at an angle less than 10°.

In the structure manufacturing method of the present invention, an intensity of the magnetic field is preferably 0.1 tesla or more.

In the structure manufacturing method of the present invention, the material of the second layer preferably contains at least one material selected from the group consisting of silicon, copper, gold, aluminum, titanium, tantalum, and tungsten.

In the structure manufacturing method of the present invention, the material of the second layer preferably contains at least one material selected from the group consisting of a refractory metal, a silicide of the refractory metal, and a nitride of the refractory metal.

In the structure manufacturing method of the present invention, the second layer preferably has an underlying layer containing at least one material selected from the group consisting of a refractory metal, a silicide of the refractory metal, and a nitride of the refractory metal, and a metal layer containing at least one material selected from the group consisting of copper, gold, and aluminum.

In the present invention, preferably, the first layer is formed from an insulating layer, the concave portion is formed from a through hole and line trench, and the second layer is formed from a conductive layer.

In the present invention, the structure is preferably an interconnection portion of a semiconductor device.

According to the present invention, when an object to be processed having a thin film deposited on a surface having a trench or hole is kept at a predetermined electric potential, and the metal film outside the trench in the surface of the object to be processed is anisotropically dry-etched by making charged particles as etchant gas particles on the object to be processed at an angle θ while making the charged particles spirally move by a magnetic field almost vertically applied to the etched surface of the object to be processed, etching of the tin metal film in the trench automatically stops at a retreat amount determined by the trench width, the speed, mass, and electric charge of the charged particles, the incident angle of the charged particles, and the field intensity. Hence, etching of the thin film in the trench automatically stops independently of the longitudinal direction of the line trench and without requiring etching end detection, and the thin metal film thickness in the trench can be accurately reproduced.

When the incident angle of the charged particles with respect to the horizontal direction of the object to be processed is 0° to 45°, and more preferably, 0° to 10°, the propagation distance of the charged particles through the trench can be shortened, and the etching amount of the thin film in the trench can be decreased. That is, the smaller the incident angle is, the shallower the depth shadowed by the shoulder portion of the trench becomes, and the smaller the retreat amount in the trench becomes.

When the intensity of the magnetic field for making the charged particles spirally move is 0.1 tesla or more, the time until the charged particles collide with the inner surface of the trench of the object to be processed is shortened, and the life time of the charged particles in the trench is also shortened. Hence, charged particles with a larger incident angle can also be used for etching. More preferably, when the intensity is 1.0 tesla or more, charged particles with a further larger incident angle can be used for etching, and the etching rate can be increased. Additionally, when the line of magnetic force of the magnetic field vertically or almost vertically crosses the surface of the object to be processed, the incident angle of the charged particles can be made small.

When the object to be processed is kept at a predetermined electric potential, the object to be processed need not be charged up. Damage to the object to be processed can be prevented, and the motion of the charged particles is not impeded.

### BRIEF DESCRIPTION OF THE DRAWINGS

FIG. 1A is a sectional view showing a state wherein a metal film is deposited on a surface with a through hole and line trench;

FIG. 1B is a schematic side view showing a state wherein the metal film outside the line trench is dry-etched;

FIG. 1C is a schematic plan view showing the relationship between the line trench and the trajectory of dry etchant gas particles;

FIG. 2 is a schematic view of a dry etching apparatus capable of executing a dry etching method of the present invention;

FIG. 3 is a schematic view of another dry etching apparatus capable of executing the dry etching method of the present invention;

FIG. 4 is a schematic view showing another structure of a permanent magnet in the dry etching apparatus shown in FIG. 3;

FIG. 5A is a sectional view showing a state wherein a metal film is deposited in a through hole;

FIG. 5B is a view showing the metal film shown in FIG. 5A is dry-etched;

FIG. 6A is a sectional view showing a state wherein a metal film is deposited on a surface with a through hole and line trench; and

FIG. 6B is a view showing a state wherein the metal film shown in FIG. 6A is dry-etched.

### DETAILED DESCRIPTION OF THE PREFERRED EMBODIMENTS

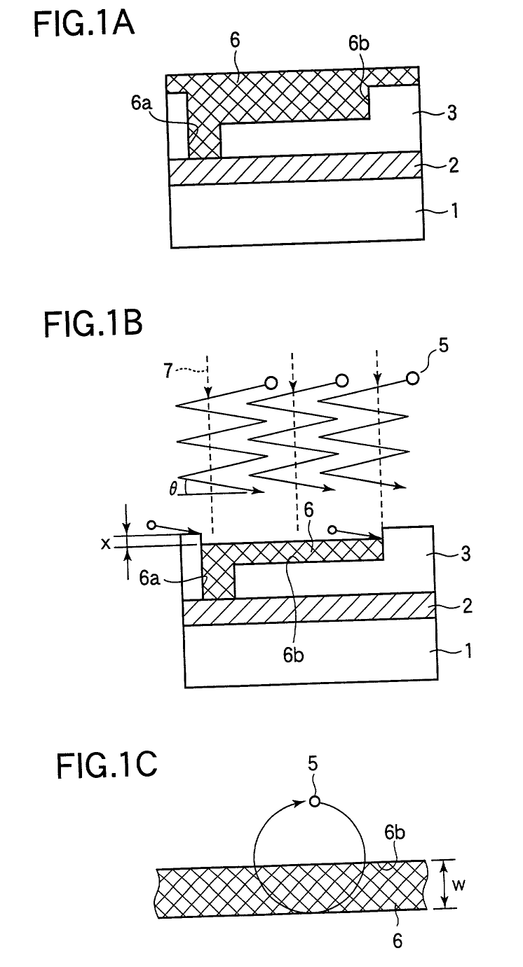

The embodiments of the present invention will be described with reference to the accompanying drawings. FIGS. 1A to 1C are views for explaining a dry etching method according to the present invention. FIG. 1A is a sectional view showing a state wherein a metal film is deposited on a surface with a through hole and line trench, FIG. 1B is a schematic side view showing a state wherein the metal film outside the line trench is dry-etched, and FIG. 1C is a schematic plan view showing the relationship between the line trench and the trajectory of dry etchant gas particles.

In the dry etching method of the present invention, the object to be processed (object to be etched) may be a multilayered structure in which layers of different materials are stacked. More specifically, it can be a multilayered structure having at least two of a metal layer, semiconductor layer and insulating layer. Alternatively, the object to be processed (object to be etched) may be a semi-fabricated or finished semiconductor element having a metal layer that can be a metal interconnection pattern.

The first layer to be used in the present invention, in which a trench and/or a hole is to be formed, is preferably formed from an inorganic insulating material or organic insulating material. More specifically, at least one material selected from the group consisting of silicon oxide, silicon nitride, silicon oxynitride, PSG (PhosphoSilicate Glass), BSG (BoroSilicate Glass), BPSG (BoroPhosphoSilicate Glass), fluorinated silicate glass, HSQ (Hydrogen SilsesQuioxane), amorphous carbon, diamond-like carbon, BCB (BenzoCycloButene), MSQ (Methyl SilsesQuioxane), PTFE (PolyTetraFluoroEthylene), Parylene-N, Parylene-F, and polyimide is preferably used.

The second layer to be used in the present invention can be formed from at least one material selected from the group consisting of a semiconductor such as silicon, a conductor such as aluminum, a refractory metal such as copper, gold, titanium, tantalum, tungsten, platinum, cobalt, nickel, vanadium, or ruthenium, a suicide of a refractory metal, and a nitride of a refractory metal. The second layer may be formed in a concave portion.

Especially, the second layer preferably has: an underlying layer such as a barrier metal containing at least one material selected from the group consisting of a refractory metal, a silicide of a refractory metal, and a nitride of a refractory metal; and a metal layer containing at least one material selected from the group consisting of copper, gold, and aluminum.

The dry etching method of the present invention will be described with reference to FIGS. 1A to 1C. Referring to FIG. 1A, after a first interconnection layer 2 is formed on a first interlayer 1, a second interlayer 3 is formed, and a through hole 6a and line trench 6b as a concave portion are formed. The through hole 6a and line trench 6b are formed by individually forming and etching predetermined resist patterns on the second interlayer 3 by photolithography. After that, a metal film (second interconnection layer) 6 is deposited on the second interlayer 3 and buried in the concave portion formed from the through hole 6a and line trench 6b.

A thus formed object to be processed for a semiconductor device is kept at a predetermined electric potential. A magnetic field 7 is vertically applied to the surface to be processed (surface to be etched) of the object to be processed, and simultaneously, the object to be processed is irradiated with charged particles 5 as etchant gas particles extracted from a plasma generation container. At this time, the charged particles 5 are trapped by the magnetic field 7 applied at a predetermined intensity B and strike the metal film 6 of the object to be processed at an incident angle θ while spirally moving. In this way, the charged particles 5 in spiral motion are made to strike the metal film 6 of the object to be processed, thereby anisotropically dry-etching the metal film 6.

For the charged particles 5 in the magnetic field, let V, m, and q be the speed, mass, and electric charge of the charged particles, respectively. Letting θ be the incident angle of the charged particles, and B be the field intensity, the charged particles 5 spirally move toward the object to be processed at a speed Vsinθ (vertical component) while rotationally moving at

cyclotron frequency ω=|q|B/m (1)

Larmor Radius r=Vcosθ/ω (2)

FIGS. 1B and 1C are side and plan views showing this state. Especially, FIG. 1C shows the relationship between the line trench 6b (trench width w) and the trajectory of the charged particles 5.

A longest time t in which the charged particles 5 cross the line trench 6b (trench width w) of the object to be processed is given by

t=2·arccos(1−w/r)/ω) (3)

A distance x through which the charged particles 5 drop in the line trench 6b during this time (i.e., the distance through which the charged particles 5 drop without colliding with the inner surface) is given by

x=t·V·sinθ=2·V·sinθ arccos(1−w/r)/ω=2·V·m·sinθ arccos{1−|q|·B·w/(V·m·cosθ)}/(|q|·B) (4)

Since the charged particles 5 that collide with the inner surface or edge of the line trench 6b cannot enter the line trench 6 anymore, the distance x through which the charged particles 5 drop in the line trench 6b is the retreat amount by etching. Etching of the thin film in the trench automatically stops at the retreat amount x.

When the object to be processed is kept at a predetermined electric potential, the object to be processed need not be charged up, so the object to be processed is not damaged, and the motion of the charged particles is not impeded.

The incident angle θ of the charged particles 5 with respect to the horizontal direction of the object to be processed is a factor for regulating the etching amount of the thin film in the trench in relation to the vertical speed component of the charged particles 5 for the object to be processed. When the incident angle θ is 0° to 45°, the etching amount of the thin film in the trench can be reduced by shortening the distance through which the charged particles 5 vertically propagate through the trench. More preferably, when the incident angle θ is 0° to 10°, the etching amount of the thin film in the trench of the object to be processed can be made very small. That is, the smaller the incident angle θ becomes, the shallower the depth shadowed by the shoulder portion of the trench becomes, and the smaller the retreat amount in the trench becomes.

When the intensity B of the magnetic field 7 is 0.1 tesla or more, the time until the charged particles 5 collide with the inner surface of the trench 6b of the object to be processed is shortened, and the life time of the charged particles in the trench is also shortened. Hence, charged particles with a larger incident angle can also be used for etching. When the intensity B of the magnetic field is 1.0 tesla or more, charged particles with a further larger incident angle can be used for etching, and the etching rate can be increased. Additionally, when the line of magnetic force crosses the surface of the object to be processed vertically or at an angle smaller than 10°, the incident angle of the charged particles can be made small. As described above, as the incident angle of the charged particles becomes small, the depth portion not shadowed by the shoulder (edge) portion of the trench becomes shallower and smaller, and the retreat amount in the trench becomes small.

All the particles incident on the object to be processed are preferably charged. If particles other than the charged particles, which are not affected by the magnetic field 7, enter the trench of the object to be processed, the particles other than the charged particles act on etching of the thin film in the trench, and the thickness of the thin film in the trench cannot be accurately reproduced. To prevent this problem, in the present invention, most particles incident on the object to be processed are charged whereby the thickness of the thin film in the trench is accurately reproduced while preventing the thin film in the trench from being etched by particles other than the charged particles. The etching method of the present invention is particularly useful for a dual damascene process.

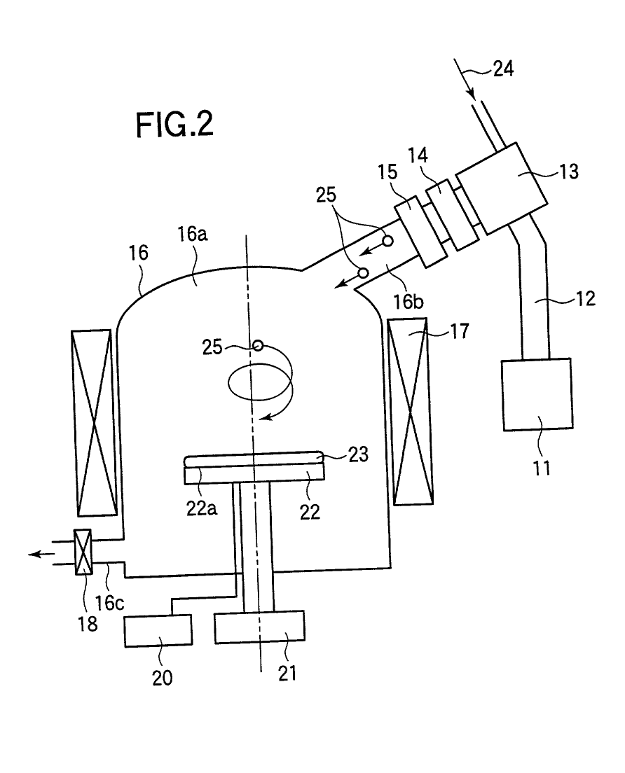

A dry etching apparatus capable of executing the dry etching method of the present invention will be described next with reference to FIG. 2.

Referring to FIG. 2, a plasma generation vessel 13 is designed to supply through a waveguide 12 a microwave oscillated by a microwave oscillation unit 11 and also supply a gas 24 from a gas cylinder (not shown). The plasma generation vessel 13 is connected to an accommodation space 16a of a reactor 16 through an extraction unit 14 for extracting only charged particles 25 from a plasma generated in the plasma generation container, a collimator 15, and a charged particle supply path 16b.

The accommodation space 16a in the reactor 16 is evacuated and kept at a low pressure by a vacuum pump 18 connected through an exhaust path 16c. The accommodation space 16a is also thermally insulated by a means (not shown) such that the temperature can be controlled. An electromagnetic coil 17 is wound around the reactor 16. Upon receiving a power for a control unit (not shown), the electromagnetic coil 17 generates a vertical magnetic field in the reactor 16, i.e., a magnetic field that acts on an object 23 to be processed in the vertical or almost vertical direction. The intensity of the magnetic field can be appropriately controlled. The electromagnetic coil 17 is kept cooled by a cooler (not shown). The electromagnetic coil 17 is surrounded by a magnetic shield (not shown) to shield the magnetic field.

A processed object holding means is arranged in the accommodation space 16a in the reactor 16. More specifically, a chuck 22 for fixing the object 23 such as a wafer to be processed is provided. The chuck 22 is driven at a low speed by a drive unit 21 to rotate on its axis. A constant electric potential control unit 20 is connected to the object 23 to be processed and/or chuck 22 to set the etched surface side electric potential of the object 23 to be processed to a positive electric potential and maintain the electric potential. The charged particle supply path 16b communicates with the reactor 16 while tilting against a line perpendicular to a holding surface 22a of the chuck 22.

In the dry etching apparatus having the above arrangement, upon receiving the gas 24 and, through the waveguide 12, a microwave oscillated by the microwave oscillation unit 11, the plasma generation vessel 13 ionizes the gas 24 and generates a plasma. The extraction unit 14 extracts only the charged particles 25 from the plasma and supplies the charged particles 25 to the reactor 16 through the collimator 15 and charged particle supply path 16b. At this time, the incident angle of the charged particles 25 on the processed surface of the object 23 to be processed which is set in the accommodation space 16a in the reactor 16 is adjusted to a desired value by the extraction direction of the extraction unit 14. The variation in incident angle of the charged particles 25 can be adjusted within a desired range by the collimator 15.

In the accommodation space 16a in the reactor 16, the object 23 to be processed is held by the chuck 22, and the object 23 to be processed is kept at a predetermined electric potential by the constant electric potential control unit 20. The object 23 to be processed can also be prevented from being charged by alternately extracting positive and negative charged particles 25 into the reactor 16 by the extraction unit 14. A power is supplied to the electromagnetic coil 17 to vertically apply a magnetic field to the processed surface of the object 23 to be processed.

The charged particles 25 reaching the reactor 16 are trapped by the magnetic field applied by the electromagnetic coil 17 and strike and collide with the processed surface of the object 23 to be processed at the incident angle θ while spirally moving. With this action, the metal film on the surface of the object 23 to be processed, i.e., the metal film outside the line trench is anisotropically etched. The metal film in the line trench is also slightly anisotropically etched and slightly retreats from the processed surface. Since the charged particles 25 are incident at the incident angle θ while spirally moving, etching of the thin film in the line trench automatically stops at the retreat amount x (according to equation (4) described above) that is determined by the trench width w of the line trench, the speed V, mass m, and electric charge q of the charged particles, the incident angle θ of the charged particles, and the field intensity B independently of the longitudinal length of the line trench, as described above. The incident angle 0 is determined by the collimator 15 and the particle extraction direction.

With the above-described dry etching apparatus, dry etching was executed using chlorine gas as a gas to be supplied while setting the field intensity B to 0.2 tesla, the charged particles extraction energy to 1 eV, the collimator transmission angle to 3° (one side), the incident angle θ onto a wafer as an object to be processed to 0.5°, and the line trench width on the processed surface of the wafer to 1.5 μm. Etching of the metal film in the line trench automatically stopped at a position retreated from the processed surface of the wafer by 19 nm.

As the material of the thin film deposited on the object to be processed, a polysilicon film, a refractory metal film as an interconnection metal film, a nitride film or silicide film of a refractory metal, or an alloy film containing copper, aluminum, titanium, or tantalum can be used. Any other material described above may be used.

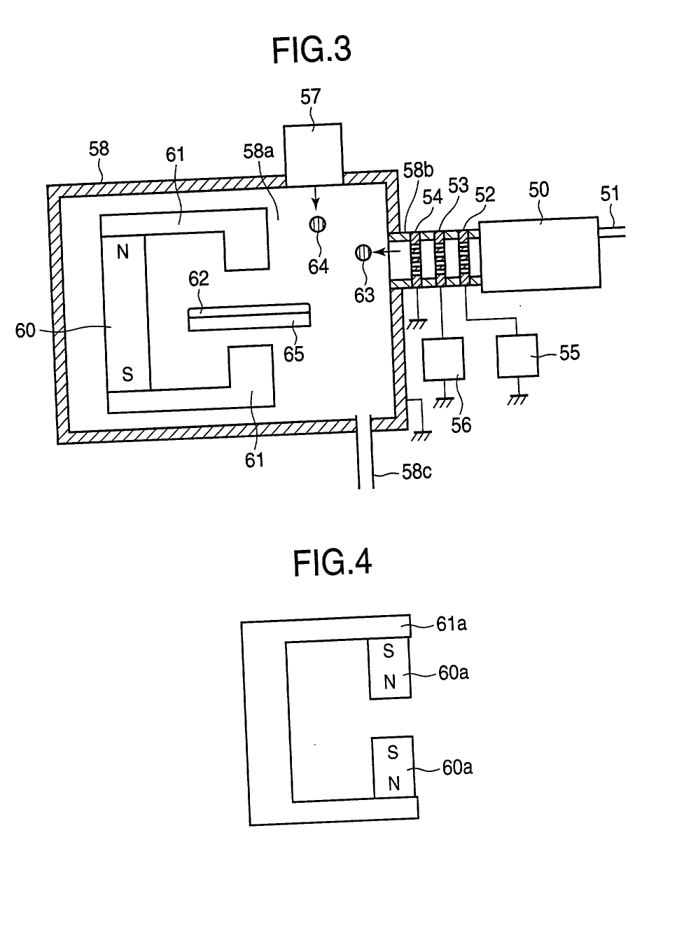

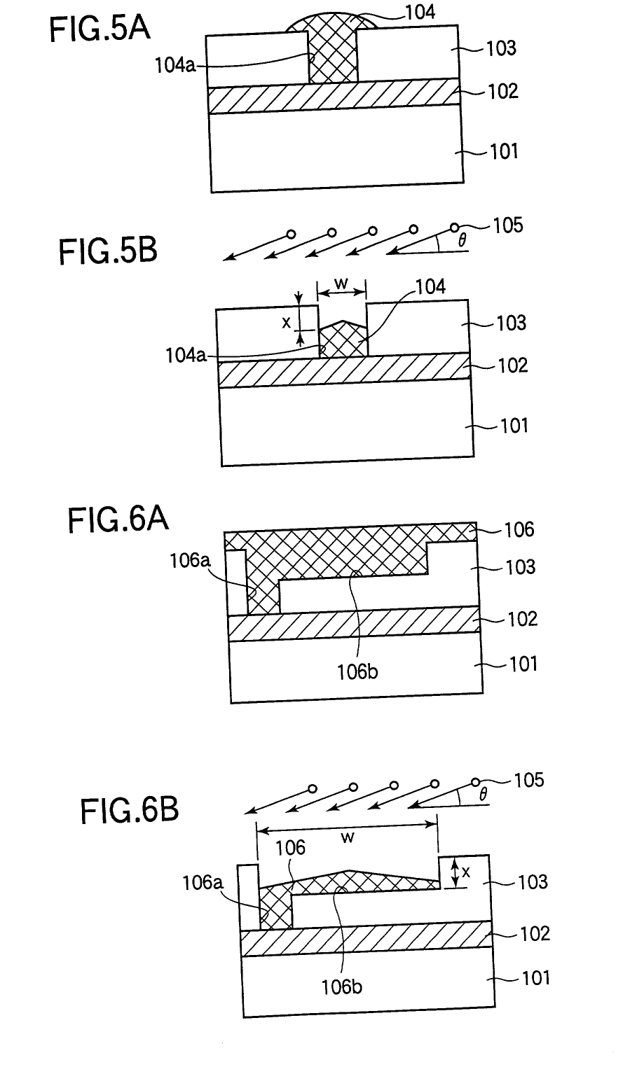

Another dry etching apparatus capable of executing the dry etching method of the present invention will be described next with reference to FIG. 3.

Referring to FIG. 3, a plasma ion source 50 generates ions by receiving a reactive gas from a reactive gas supply port 51. This plasma ion source can be constructed as a Kaufmann type or bucket type and preferably generates low-energy ions. The plasma ion source 50 is connected to an accommodation space 58a in a reactor 58 through a first electrode 52, second electrode 53, and third electrode 54 for accelerating/decelerating the ions generated by the plasma ion source 50, and then through an ion supply path 58b. The first electrode 52 is connected to a negative acceleration power supply 55 and acts to extract positive ions. The second electrode 53 is connected to a positive deceleration power supply 56 and acts to decelerate the positive ions extracted by the first electrode 52 to give a desired energy. The third electrode 54 is grounded together with the reactor 58. With this arrangement, positive ions 63 generated by the plasma ion source 50 are extracted from the plasma ion source 50 by electric fields generated by the first electrode 52 and second electrode 53, decelerated by electric fields generated by the second electrode 53 and third electrode 54, and guided into the accommodation space 58a in the reactor 58.

An electron gun 57 is designed to extract, by an extraction electrode, thermoelectrons output from a thermoelectron source such as a heater into the reactor 58. Electrons 64 supplied from the electron gun 57 to the accommodation space 58a in the reactor 58 act to electrically neutralize an object 62 such as a wafer to be processed, which is charged up by positive ions, and suppress damage to the object to be processed.

A processed object holding means (to be simply referred to as a chuck hereinafter) 65 for holding the object 62 such as a wafer to be processed is provided in the accommodation space 58a in the reactor 58. The chuck 65 is preferably formed from a material that readily passes a magnetic force. An electrostatic attraction function for holding the object 62 to be processed or a heater for heating the object 62 to be processed may be added as needed.

In the reactor 58, a permanent magnet 60 for generating a magnetic field around the object 62 to be processed, which is held by the chuck 65, is arranged. A pair of yokes 61 of the permanent magnet 60 sandwich the object 62 to be processed such that the line of magnetic force of the permanent magnet 60 becomes perpendicular or almost perpendicular to the surface of the object 62 to be processed. The surface magnetic force of the permanent magnet 60 is about 1.5 tesla. A magnetic field of about 1 tesla is obtained on the surface of the object 62 to be processed by adjusting the distance between the yoke 61 and the object 62 to be processed by a means (not shown). As the permanent magnet 60, an alnico magnet can be used. A cooling means or heat insulation means is added as needed to keep the temperature of the permanent magnet 60 to a predetermined value or less. As the combined structure of the permanent magnet and yokes, in addition to the structure shown in FIG. 3, two permanent magnets 60a and 60b may be arranged to oppose each other and connected by a U-shaped yoke 61a, as shown in FIG. 4. In place of the permanent magnet, an electromagnet may be used.

The reactor 58 has a gas exhaust port 58c. The gas in the reactor 58 is exhausted through the gas exhaust port 58c by a means such as a vacuum pump (not shown), thereby holding a low pressure in the reactor 58.

The processed object etching operation by the etching apparatus with the above arrangement will be described.

As the wafer 62 as an object to be processed, a wafer having a size of 50 mm (2 inches) is used. A 1.5-μm or less wide trench and hole have been formed in the processed surface, and a thin copper film has been deposited. The wafer 62 is placed on the chuck 65 and heated to about 300° C. by a heater (not shown) incorporated in the chuck 65.

The positive ions 63 generated by the plasma ion source 50 are extracted from the plasma ion source 50 by the electric fields generated by the first electrode 52 and second electrode 53, decelerated by the electric fields generated by the second electrode 53 and third electrode 54, and guided into the accommodation space 58a in the reactor 58. The energy of the positive ions 63 extracted into the accommodation space 58a in the reactor 58 can be controlled by the voltage of the acceleration power supply 55 connected to the first electrode 52, the voltage of the deceleration power supply 56 connected to the second electrode 53, and the distance between the electrodes. The extraction direction of the ions 63 can be controlled by the angle of electrode installation. In this case, the ions 63 are controlled to fly at an energy of 5 eV and an incident angle of 7° or less with respect to the processed surface of the wafer 62. As a reactive gas, i.e., an ion source, chlorine is used.

The positive ions 63 supplied into the accommodation space 58a in the reactor 58 are trapped by the magnetic field generated by the permanent magnet 60 and collide with the wafer 62 while spirally moving. The surface field of the wafer 62 is controlled to 1 tesla by adjusting the distance between the yoke 61 and the wafer 62. The direction of the line of magnetic force is controlled to a direction perpendicular to the surface of the wafer 62. The ions 63 collide with the wafer 62 while being controlled to a Larmor Radius of 1.9e3 to 2.3e3 μm.

When the wafer 62 obtains a positive charge due to collision of the ions 63, the element on the wafer 62 may break, or the trajectory of the ions 63 may be bent. To prevent this, the electrons 64 are intermittently supplied for the electron gun 57 into the reactor 58. During supply of the electrons 64, the ions 63 are not extracted from the plasma ion source 50. The time interval of intermittent supply of the electrons 64 is adjusted such that the processed surface of the wafer 62 has a slightly positive electric potential.

In the above-described way, the ions 63 are controlled by the permanent magnet 60, first electrode 52, second electrode 53, acceleration power supply 55, and deceleration power supply 56 to have an energy of 5 eV, a Larmor Radius of 1.9e3 to 2.3e3 μm, and an incident angle of 7° or less and collide with the wafer 62. Since the ions 63 collided with the wafer 62 while spirally moving, the thin copper film deposited on the surface of the wafer 62 was etched except the thin copper film deposited in the 1.5 μm or less wide trench and hole formed in the surface of the wafer 62. At this time, although the film at the upper portion of the trench and hole was etched by about 0.02 μm, the thin copper film on the lower side was not etched.

As has been described above, according to the present invention, an object to be processed in which a thin film is deposited on a surface having a trench or hole is kept at a predetermined electric potential, and charged particles as etchant gas particles are made to spirally move by a magnetic field vertically or almost vertically applied to the object to be processed and to strike the object to be processed at the angle θ, thereby anisotropically dry-etching the metal film outside the trench on the surface of the object to be processed. Etching of the thin film in the trench automatically stops at a retreat amount determined by the trench width, the speed, mass, and electric charge of the charged particles, the incident angle of the charged particles, and the field intensity. Hence, etching of the thin film in the trench automatically stops independently of the longitudinal direction of the line trench and without requiring etching end detection, and the metal film thickness in the trench can be accurately reproduced.

What is claimed is:

1. A dry etching method of irradiating an object to be processed, which has a thin film deposited on a surface thereof having a trench or hole, with charged particles to remove the thin film outside the trench or hole, comprising the steps of:
making the charged particles spirally move by a magnetic field substantially vertically applied to the object to be processed;
maintaining the object to be processed at a positive electric potential; and
making the charged particles incident on the object to be processed, thereby anisotropically dry etching the thin film.

2. A method according to claim 1, further comprising the step of keeping the object to be processed at a predetermined electric potential.

3. A dry etching method of irradiating an object to be processed, which has a thin film deposited on a surface thereof having a trench or hole, with charged particles to remove the thin film outside the trench or hole, comprising the steps of keeping the object to be processed at a predetermined electric potential, making the charged particles incident on the object to be processed while making the charged particles spirally move by a magnetic field substantially vertically applied to the object to be processed, thereby anisotropically dry etching the thin film.

4. A method according to claim 1 or 3, wherein the charged particles are incident at an angle of 0° to 45° with respect to a horizontal direction of the object to be processed.

5. A method according to claim 1 or 3, wherein the magnetic field is applied while making a line of magnetic force cross the surface of the object to be processed vertically or at an angle less than 10°.

6. A method according to claim 1 or 3, wherein an intensity of the magnetic field is not less than 0.1 tesla.

7. A method according to claim 1 or 3, wherein the thin film deposited on the object to be processed is formed from a material selected from the group consisting of a polysilicon film, a nitride film and silicide film of a refractory metal as an interconnection metal film, and alloy films containing copper, aluminum, titanium, and tantalum.

8. A dry etching apparatus having processed object holding means for holding an object to be processed, a reactor capable of accommodating said processed object holding means in an accommodation space, and plasma generation means for supplying charged particles to the accommodation space, comprising charged particle spiral motion means, arranged around the accommodation space, for making the charged particles spirally move.

9. An apparatus according to claim 8, wherein said charged particle spiral motion means is arranged around the processed object holding means accommodated in the accommodation space.

10. An apparatus according to claim 8, wherein said charged particle spiral motion means is arranged at a position where the charged particles can be made to spirally move on the processed object holding means.

11. An apparatus according to claim 8, wherein said charged particle spiral motion means has an electromagnetic coil or permanent magnet.

12. An apparatus according to claim 11, wherein said charged particle spiral motion means generates a magnetic field having a line of magnetic force that crosses a surface of the object to be processed, which is held by the processed object holding means, vertically or at an angle less than 10°.

13. An apparatus according to claim 8, wherein the reactor has a charged particle supply path tilted with respect to a line perpendicular to a holding surface of the processed object holding means.

14. An apparatus according to claim 8, further comprising control means for controlling an incident angle and/or a variation in incident angle of the charged particles on the processed object holding means.

15. A method of manufacturing a structure in which a concave portion formed in a first layer is filled with a material different from that of the first layer, comprising the steps of:
depositing a second layer made of the material on an upper surface of the first layer having the concave portion; and
executing dry etching to remove the second layer deposited outside the concave portion,
wherein the dry etching step comprises the step of maintaining an etched surface side at a predetermined electric potential and substantially vertically applying a magnetic field to the etched surface to make charged particles become incident on the etched surface while spirally moving.

16. A method according to claim 15, wherein the etched surface side is controlled to have a positive electric potential.

17. A method according to claim 15, wherein the charged particles become incident at an angle of 0° (exclusive) to 45° (inclusive) with respect to a direction parallel to the etched surface.

18. A method according to claim 15, wherein the magnetic field is applied while making a line of magnetic force cross the etched surface vertically or at an angle less than 10°.

19. A method according to claim 15, wherein an intensity of the magnetic field is not less than 0.1 tesla.

20. A method according to claim 15, wherein the material of the second layer contains at least one material selected from the group consisting of silicon, copper, gold, aluminum, titanium, tantalum, and tungsten.

21. A method according to claim 15, wherein the material of the second layer contains at least one material selected from the group consisting of a refractory metal, a silicide of the refractory metal, and a nitride of the refractory metal.

22. A method according to claim 15, wherein the second layer has an underlying layer containing at least one material selected from the group consisting of a refractory metal, a silicide of the refractory metal, and a nitride of the refractory metal, and a metal layer containing at least one material selected from the group consisting of copper, gold, and aluminum.

23. A method according to claim 15, wherein the first layer is formed from an insulating layer, the concave portion is formed from a through hole and line trench, and the second layer is formed from a conductive layer.

24. A method according to claim 15, wherein the structure is an interconnection portion of a semiconductor device.
